(19) United States
(12) Patent Application Publication
(10) Pub. No.: US 2016/0351273 A1
(43) Pub. Date: Dec. 1, 2016

(54) ONE-TIME PROGRAMMABLE (OTP)/ READ ONLY (RO) DATA STORAGE DEVICE

(71) Applicant: HCL Technologies Limited, Noida (IN)

(72) Inventor: Siva Sakthivel SADASIVAM, Ambattur (IN)

(21) Appl. No.: 15/081,016

(22) Filed: Mar. 25, 2016

(30) Foreign Application Priority Data
May 25, 2015 (IN) 1483/DEL/2015

(51) Int. Cl. G11C 17/18; G11C 17/16

(52) U.S. Cl. CPC G11C 17/18; G11C 17/16

(57) ABSTRACT

A One-Time Programmable (OTP)/Read Only (RO) data storage device is disclosed. The OTP/RO data storage device comprises a One-Time Programmable (OTP)//Read Only (RO) memory, an interface and a controller. The OTP/RO memory stores data. The interface connects the OTP/RO memory to a host device. The controller allows the host device to read the data and restricts the host device to write new data in the OTP/RO memory, via the interface.

### CROSS REFERENCE TO RELATED APPLICATIONS

The present application claims benefit from Indian Complete Patent Application No. 1483/DEL/2015, filed on May 25 2015, the entirety of which is hereby incorporated by reference.

### TECHNICAL FIELD

The present disclosure generally relates to the field of data storage devices and more particularly, to a One-Time Programmable (OTP)/Read Only (RO) data storage device.

### BACKGROUND

Small data storage devices are gaining popularity because of their compact size and convenience. Typically, compact data storage devices include a Universal Serial Bus (USB) flash drive, a micro secure digital card and so on.

FIG. 1 shows a typical prior art, data storage device 100. Generally, the data storage device 100 includes a memory 102, an interface 104, a controller 106 and a switch 110, as shown in FIG. 1. The memory 102 stores data, the interface 104 enables connection between the memory 102 and a host device (not shown) such as a computer. The controller 106 controls the read operation and write operation in the memory 102. The controller 106 may receive commands for the read operation and the write operation from the host device. The switch 110 is provided to decide to make the write operation in the memory 102. The switch 110 may be provided to protect saved files, data or applications in the data storage device 100, as a write-protect material. Typically, the switch 110 is provided externally to the data storage device 100 such that a user can control the write operation. The switch may have a ON or OFF state to decide if the user want to make the write protection.

Use of Read/Write memory increases cost by adding switch 110 to control the write operation increases cost of hardware to manufacture the data storage device 100. The switch 110 is also not a failsafe feature to protect data in the memory. Further, the data stored in the memory 102 may be tampered leading to loss of data permanently.

### SUMMARY

This summary is provided to introduce concepts related to a One-Time Programmable (OTP)/Read Only (RO) data storage device and the concepts are further described below in the detailed description. This summary it is not intended for use in determining or limiting the scope of the claimed subject matter.

In one implementation, a One-Time Programmable (OTP)/Read Only (RO) data storage device is disclosed. The OTP data storage device includes a One-Time Programmable (OTP)/Read Only (RO) memory, an interface and a controller. The OTP memory stores data. The data is written only once to the OTP data storage device. The OTP/RO memory stores data. The data is written at a manufacturing stage of the OTP data storage device. The interface connects the OTP/RO memory to a host device. The controller allows the host device to read the data and restricts the host device to write new data in the OTP/RO memory, via the interface.

### BRIEF DESCRIPTION OF DRAWINGS

The detailed description is described with reference to the accompanying figures. In the figures, the left-most digit(s) of a reference number identifies the figure in which the reference number first appears. The same numbers are used throughout the drawings to refer like/similar features and components.

FIG. 1 illustrates a USB flash drive from prior art.

FIG. 2 illustrates a One-Time Programmable (OTP)/Read Only (RO) data storage device comprising read only memory, in accordance with an embodiment of the present disclosure.

FIG. 3 illustrates a One-Time Programmable (OTP)/Read Only (RO) data storage device comprising one time writable OTP memory, in accordance with an embodiment of the present disclosure.

FIG. 4 illustrates one or more OTP data storage devices connected to a host device, in accordance with an embodiment of the present disclosure.

### DETAILED DESCRIPTION

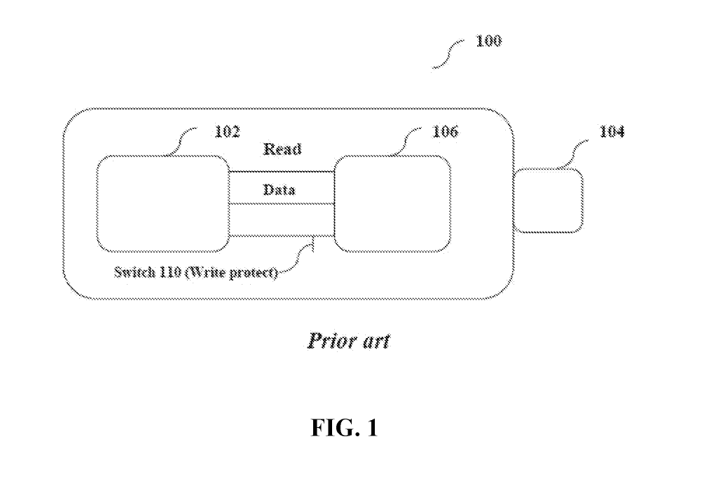

The present disclosure relates to a One-Time Programmable (OTP)/Read Only (RO) data storage device to overcome difficulties present in the prior art shown in FIG. 1. The OTP/(RO) data storage device comprises a One-Time Programmable (OTP)/Read Only (RO) memory, an interface and a controller. The OTP/RO memory stores data. The data is stored in the OTP memory at a time of manufacturing the OTP data storage device. The OTP memory may include USB flash memory, secure digital cards, micro cards, and so on. The interface connects the OTP memory to a host device. The host device may include, but is not limited to, a computer, a mobile phone, a laptop, a server and so on. When the OTP memory is connected to the host device, the controller allows the host device to read the data and restricts the host device to write new data in the OTP memory, via the interface.

While aspects of described OTP data storage system may be implemented in any number of different computing systems, environments, and/or configurations, the embodiments are described in the context of the following exemplary system.

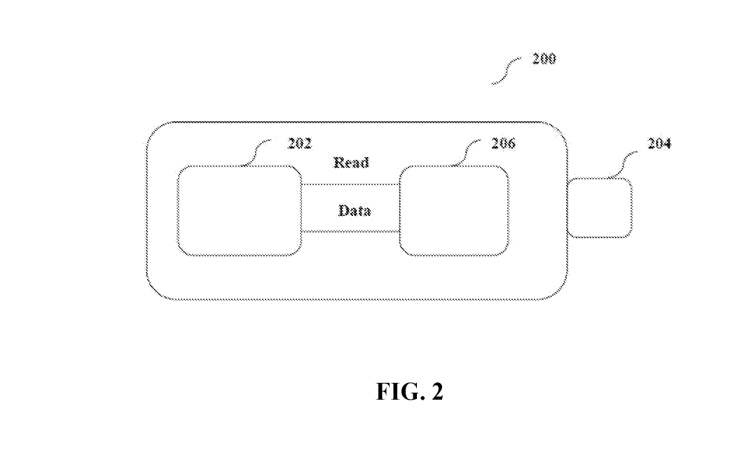

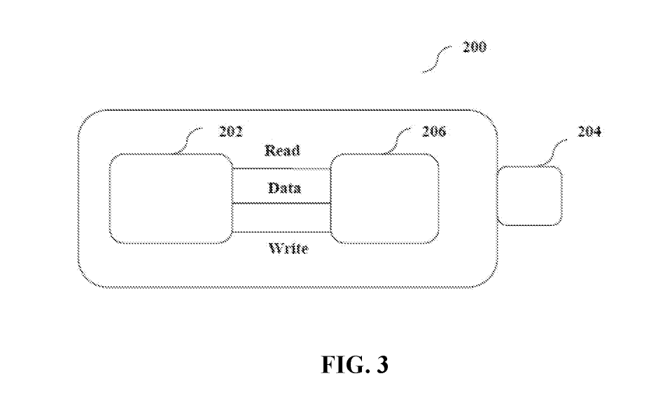

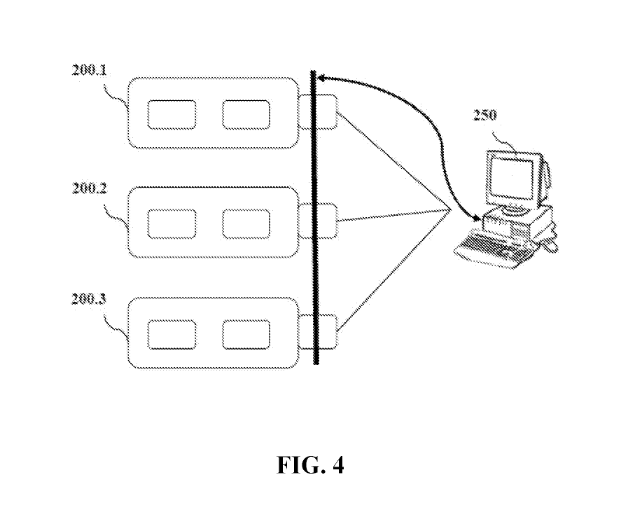

Referring to FIG. 2, FIG. 3 and FIG. 4, a One-Time Programmable (OTP)/Read Only (RO) data storage device 200 connected to a host device 250 is illustrated, in accordance with an embodiment of the present disclosure. In one example, the OTP/RO data storage device 200 may include, but not limited to, a USB flash drive, a secured digital memory card, a hard disk, and so on. The host device 250 may comprise one of a computer, a mobile phone, a laptop, an electronic device, and so on. The OTP data storage device 200 may comprise a One-Time Programmable (OTP)/Read Only (RO) memory 202, an interface 204 and a controller 206.

The OTP memory 202 may include any computer-readable medium known in the art including, for example, a volatile memory, such as static random access memory (SRAM) and dynamic random access memory (DRAM), and/or non-volatile memory, such as read only memory (ROM), flash memories, hard disks, and so on. The OTP memory 202 may store data. In one example, the data may include, but not limited to, an audio file, a video file, an application, a program, and so on.

The interface 204 may include one of: a Universal Serial Bus (USB) interface and a Personal Computer Memory Card International Association (PCMCIA) interface. The interface 204 is used to connect the OTP memory 202 with the host device 250. In other words, the interface 204 and the host device 250 such as: computers, reading card, mobile phone, etc may be connected/coupled, enabling connection between the OTP data storage device 200 to the host device 250, so that the host device 250 can access the data in the OTP memory 202. The USB interface 204 used for connecting to the host device 250, such as computer, further includes a transceiver and serial interface engine (SIE) or parallel interface engine (PIE), and is responsible for the receiving and transmission of the USB specification version 1.1 or 2.0 or 3.0 protocol. Although the interface 204 comprising the USB interface and the PCMCIA interface is disclosed, it should be noted that other interfaces may be used to connect the OTP memory 202 to the host device 250 depending on the type of OTP data storage device used.

The controller 206 may be implemented as microcontrollers that manipulate signals based on operational instructions. The controller 206 may be configured to fetch instructions or commands from the host device 250 and execute the instructions in the OTP memory 202. In one example, the instructions may include reading the data stored in the OTP memory 202.

When the OTP memory 202 is connected to the host device 250, the controller 206 may allow the host device 250 to read the data stored in the OTP memory 250, as shown in FIG. 2. In other words, the OTP memory 202 may used as a read only memory. The data in the OTP memory 202 may be tampered with. For example, such data may be tampered by overwriting the data with new data or by deleting/erasing the data. In order to avoid overwriting of the data with the new data, the data stored in the OTP memory 202 may be written only once, e.g., at a manufacturing stage. For example, the data such as an audio, a video, a program and text data may be written at the manufacturing stage. After writing the data in the OTP memory 202, subsequent write operations to add new data or to delete the data existing may be restricted. Specifically, the controller 206 may allow the read operation and restrict the write operation in the OTP memory 202.

Referring to FIG. 3, the controller 206 controlling the operations in the OTP data storage device 200 is explained. The data such as a program, or an audio file may be written in the OTP memory 202 at the manufacturing stage. After writing the data, the OTP data storage device 200 may be shipped to consumers. When the consumers uses the host device 250 to access the data in the OTP data storage device 200, upon connection, the controller 206 allows the host device 250 to access the data in the OTP memory 202. If the consumer sends a command from the host device 250 to write new data in the OTP memory 202, the controller 206 restricts the write operation.

Referring to FIG. 4, one or more OTP data storage devices, such as 200.1, 200.2, 200.3, and so on may be connected to the host device 250. Each OTP data storage device 200.1, 200.2, 200.3, and so on may have their respective OTP memories (202.1, 202.2, 202.3 and so on), interfaces (204.1, 204.2, 204.3 and so on), and controllers (206.1, 206.2, 206.3 and so on). When one or more OTP data storage devices 200 are connected, the host device 250, may send commands to access the data in the OTP memory 202 of that OTP data data storage device 200. As described above, if the host device 250 sends the command to overwrite the data with the new data such as a new program or an audio file, the respective controller 206 may restrict the operation thereby protecting tampering of the data.

By providing the OTP memory 202 in the OTP data storage device 200, the data may be protected from common causes of data loss, such as deletion. Since the controller 206 allows only the read operations and restricts the write operations, the OTP data storage device operates at a faster rate. Further, the data may be retained in the OTP memory 202 for longer duration. Furthermore, cost of the OTP data storage devices 200 may be reduced.

Although implementations of One-Time Programmable (OTP)/Read Only (RO) data storage device have been described in language specific to structural features, it is to be understood that the appended claims are not necessarily limited to the specific features described. Rather, the specific features are disclosed as examples of implementations for One-Time Programmable (OTP) data storage devices.

We claim:

1. A One-Time Programmable (OTP)/Read Only (RO) data storage device comprising:
a One-Time Programmable (OTP)/Read Only (RO) memory to store data;
an interface to connect the OTP/RO memory to a host device; and
a controller to allow the host device to read the data and to restrict the host device to write new data in the OTP/RO memory, via the interface.

2. The OTP/RO data storage device of claim 1, wherein the OTP/RO data storage device is a flash drive.

3. The OTP/RO data storage device of claim 1, wherein the OTP/RO data storage device is a memory card.

4. The OTP/RO data storage device of claim 1, wherein the interface is at least one of: a USB interface and a Personal Computer Memory Card International Association (PCMCIA) interface.

5. The OTP/RO data storage device of claim 1, wherein the host device comprises one of: a computer, a portable electronic device, a laptop, and a server.
